(19) United States
(12) Patent Application Publication
(10) Pub. No.: US 2026/0058639 A1
(43) Pub. Date: Feb. 26, 2026

(54) CAPACITIVELY TRANSDUCED MICRO OR NANO ELECTROMECHANICAL RESONATOR SYSTEM AS SIGNAL AMPLIFIER

(71) Applicant: Indian Institute of Science, Kamataka (IN)

(72) Inventors: Disha Chugh, Bengaluru (IN); Saurabh A. Chandorkar, Bengaluru (IN)

(73) Assignee: Indian Institute of Science, Kamataka (IN)

(21) Appl. No.: 19/309,977

(22) Filed: Aug. 26, 2025

(30) Foreign Application Priority Data
Aug. 26, 2024 (IN) 202441064306

(51) Int. Cl. H03H 9/24; H03H 9/02; H03H 9/145

(52) U.S. Cl. CPC H03H 9/2473; H03H 9/02433; H03H 9/14544; H03H 9/2426; H03H 2009/02165; H03H 2009/02456

(57) ABSTRACT

The present disclosure relates to methods and system that provides techniques of designing amplifiers with controllable gain for electrical signals/power based on capacitively transduced Micro and/or Nano electromechanical resonators. The present disclosure provides techniques of implementing an RF voltage amplifier, a phase shift amplifier, and/or an RF power amplifier through capacitively transduced Micro/Nano electromechanical resonators. In some embodiments, the amplifier is narrow-band with the centre frequency specified by the resonant frequency of the Micro/Nano electromechanical resonators. In addition, the present disclosure provides a technique by which a set of capacitively transduced Micro/Nano electromechanical resonators are implemented as RF power amplifier with multiple inputs and multiple outputs with the output voltage being measured at electrically floating electrodes that are capacitively coupled with the resonator. These electrically-floating electrodes can also be used to sum various output signals from a resonator and signals output from various resonators.

### TECHNICAL FIELD

The present disclosure generally relates to signal amplifiers through electromechanical devices. More particularly, the present disclosure relates to a signal amplifier formed from a capacitively-transduced Micro Electro-mechanical devices or Nano Electro-mechanical devices.

### BACKGROUND

Electrical signal amplifiers are critical for various applications, such as radio transmitters, audio systems and applications, and communication devices. Such amplifiers may be used in the applications requiring signal and/or power amplification. Examples of amplifiers may include, but are not limited to, Radio Frequency (RF) voltage amplifiers, RF power amplifiers, and phase shift amplifiers (which change phase of input signal by a designated amount and amplify the amplitude of the phase-shifted signal).

The information disclosed in this background of the disclosure section is only for enhancement of understanding of the general background of the disclosure and should not be taken as acknowledgment or any form of suggestion that this information forms prior art already known to a person skilled in the art.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary presents certain concepts relating to one or more aspects relating to the mechanisms disclosed herein in a simplified form to precede the detailed description presented below.

The methods and systems of the present disclosure provide techniques of designing an electrical signal/power amplifier based on capacitively transduced Micro and/or Nano electromechanical resonators. As per the present subject matter, an electromechanical energy transformation is used for implementing electric signal/power amplifiers, instead of implementing the amplification using the standard electronic devices, such as transistors. The present subject matter proposes, transformation of capacitive energy/electrostatic energy to mechanical energy and back to capacitive/electrostatic energy to implement the electromechanical amplifier which amplifies input electrical signal/power. Based on the use of capacitively transduced electromechanical resonator, achievable level of noise performance will increase multiple folds as compared to conventional/standard electrical signal/power amplifiers which made from electronic devices, such as transistors. The present disclosure provides technique of a capacitively transduced Micro/Nano electromechanical resonator implemented as an RF voltage amplifier with a single input and a single output with the output voltage being measured at an electrically floating electrode that is capacitively coupled with the resonator. This concept can, however, be easily translated to capacitively transduced micro/nano electromechanical amplifiers with multiple inputs and multiple outputs. In some embodiments, the amplifier is a narrow-band amplifier with the centre frequency specified by the resonant frequency of the Micro/Nano electromechanical resonators. Further, the present disclosure provides technique of a micro/nano electromechanical resonator implemented as a phase shift amplifier with input voltage signal applied to actuation electrodes and the phase is shifted by tuning the resonant frequency of the electromechanical element of the resonator using bias voltage applied either to the resonator or electrodes in its vicinity. Such technique of implementing the micro/nano electromechanical resonator as the phase shift amplifier, as per the present subject matter, can be effectively translated to capacitively transduced micro/nano electromechanical amplifiers with multiple input and multiple outputs. In addition, the present disclosure provides technique of a capacitively transduced Micro/Nano electromechanical resonator implemented as an RF power amplifier with a single input and a single output with the output voltage being measured at an electrically floating electrode that is capacitively coupled with the resonator. Such technique of implementing the capacitively transduced Micro/Nano electromechanical resonator as the RF power amplifier can be effectively translated to capacitively transduced micro/nano electromechanical amplifiers with multiple input and multiple outputs.

As per the existing techniques, RF amplifiers utilize L-C resonant components to build narrowband/bandpass amplifiers in conjunction with a transistor. Such L-C oscillators suffer from low quality factors and are susceptible to noise associated with the dissipative component in a practically implemented L-C circuit as well as that emanating from the transistor itself. The proposed electromechanical amplifier solution, as per the present subject matter, does not require a transistor as an appropriately designed MEM resonator system itself acts as an amplifier as well as a filter. Thus, the overall noise figure performance of the proposed amplifier is significantly lower. Therefore, the techniques provided by the present subject matter significantly improve the noise figure of narrowband amplifiers.

Disclosed are micro or nano electromechanical resonators and methods of implementing Micro Electro-Mechanical (MEM) devices or Nano Electro-Mechanical (NEM) devices as a signal amplifier.

In one illustrative example, a capacitively transduced Micro or Nano Electro Mechanical Resonator system is provided. The capacitively transduced Micro or Nano Electro Mechanical Resonator system comprises one or more actuating units, one or more resonance units, a sensing unit, and an adaptive tuning unit.

The one or more actuating units is configured to generate one or more actuating signals based on one or more input signals. The one or more resonance units coupled to the one or more actuating units. Each of the one or more of resonance units is configured to resonate in response to the one or more actuating signals based on a value of capacitance associated with each of the one or more of resonance units. The sensing unit is capacitively coupled to the one or more resonance units. The sensing unit is configured to, in response to one or more of generation of the one or more actuating signals and resonation of the one or more of resonance units, sense one or more capacitance component, associated with the sensing unit. The adaptive tuning unit is coupled to the sensing unit, the adaptive tuning unit configured to generate a tuning signal to tune, based on at least one of the one or more capacitance component and the resonation of the one or more of resonance units, respective resonant frequency of each of the one or more of resonance units. Further, the adaptive tuning unit configured to selectively generate, based on the tuning, one or more amplified output signals.

In another example, a method for implementing Micro Electro-Mechanical (MEM) devices or Nano Electro-Mechanical (NEM) devices as a signal amplifier is provided. The method comprises generating, by one or more actuating units, one or more actuating signals based on one or more input signals. Further, the method comprises resonating each of one or more of resonance units coupled to the one or more actuating units, in response to the one or more actuating signals based on a value of capacitance associated with each of the respective one or more of resonance units. The method further comprises sensing, by the sensing unit capacitively coupled to the one or more resonance units and in response to one or more of generation of the one or more actuating signals and resonation of the one or more of resonance units, one or more capacitance component, associated with the sensing unit. Furthermore, the method comprises generating, by an adaptive tuning unit coupled to the sensing unit, a tuning signal to tune, based on at least one of the one or more capacitance component and the resonation of the one or more of resonance units, respective resonant frequency of each of the one or more of resonance units. The method further comprises selectively generating, by the adaptive tuning unit coupled to the sensing unit, based on the tuning, one or more amplified output signals.

Other advantages associated with the aspects disclosed herein will be apparent to those skilled in the art based on the accompanying drawings and detailed description.

### BRIEF DESCRIPTION OF THE DRAWINGS

The embodiments of the disclosure itself, as well as a preferred mode of use, further objectives, and advantages thereof, will best be understood by reference to the following detailed description of an illustrative embodiment when read in conjunction with the accompanying drawings. One or more embodiments are now described, by way of example only, with reference to the accompanying drawings in which:

FIGS. 1a-1c illustrate schematic diagrams of Double Ended Tuning Fork (DETF) resonator;

FIG. 2 illustrates a block diagram of a capacitively transduced Micro or Nano Electro-mechanical resonator system, in accordance with an embodiment of the present disclosure;

FIG. 3 illustrates a schematic diagram of a capacitively transduced MEM resonator system, in accordance with some embodiments of the present disclosure;

FIG. 4 illustrates a schematic diagram of a system of electrostatically sensed micro/nano-electromechanical resonators, in accordance with some embodiments of the present disclosure;

FIG. 5 illustrates a schematic diagram of an example system where voltage output of k resonators is collected at the same sensing electrode, in accordance with some embodiments of the present disclosure;

FIG. 6 illustrates a circuit schematic of a capacitively transduced MEM resonator system for floating voltage sensing, in accordance with some embodiments of the present disclosure;

FIG. 7 illustrates (a) coupled spring-mass system equivalent of the DETF resonator and its circuit schematic when a voltage signal is measured at the sensing electrode and (b) equivalent circuit at output node of the electro-mechanical system depicted in (a).

FIG. 8 illustrates an equivalent circuit diagram of a combined system of a resonator and a sense amplifier/buffer when transduced and sensing capacitances are viewed as dependent sources, in accordance with some embodiments of the present disclosure;

FIG. 9 illustrates an equivalent circuit diagram of a combined system of a resonator and a load-resistor, when transduced and sensing capacitances are viewed as dependent sources, in accordance with some embodiments of the present disclosure;

FIG. 10 illustrates circuit schematic of an example system where voltage output of two resonators is collected at the same electrically floating sensing electrode, in accordance with some embodiments of the present disclosure;

FIG. 11 illustrates a schematic representation of parameters required for designing a complete equivalent circuit diagram of an exemplary system of electrostatically sensed micro/nano-electromechanical resonators, in accordance with some embodiments of the present disclosure;

FIG. 12 illustrates a schematic diagram of DETF resonator with multiple actuation and sensing points along with the sensing element, in accordance with some embodiments of the present disclosure;

FIG. 13 illustrates an equivalent circuit diagram of the combined system of the resonator and the sensing element with multiple inputs and outputs, in accordance with some embodiments of the present disclosure;

FIG. 14 illustrates an equivalent circuit diagram of the combined system of the resonator and the sensing element with single input and single output, in accordance with some embodiments of the present disclosure; and

FIG. 15 illustrates a flowchart of a method for for implementing Micro Electro-mechanical (MEM) resonator systems or Nano Electro-mechanical (NEM) resonator systems as a signal amplifier, in accordance with some embodiments of the present disclosure an aspect of the subject matter in accordance with one embodiment.

The figures depict embodiments of the disclosure for purposes of illustration only. One skilled in the art will readily recognize from the following description that alternative embodiments of the structures and methods illustrated herein may be employed without departing from the principles of the disclosure described herein.

### DESCRIPTION OF THE DISCLOSURE

In the present document, the word “exemplary” is used herein to mean “serving as an example, instance, or illustration.” Any embodiment or implementation of the present subject matter described herein as “exemplary” is not necessarily to be construed as preferred or advantageous over other embodiments.

While the disclosure is susceptible to various modifications and alternative forms, specific embodiment thereof has been shown by way of example in the drawings and will be described in detail below. It should be understood, however that it is not intended to limit the disclosure to the particular forms disclosed, but on the contrary, the disclosure is to cover all modifications, equivalents, and alternative falling within the spirit and the scope of the disclosure.

The terms “comprises”, “comprising”, or any other variations thereof, are intended to cover a non-exclusive inclusion, such that a setup, device, or method that comprises a list of components or steps does not include only those components or steps but may include other components or steps not expressly listed or inherent to such setup or device or method. In other words, one or more elements in a device or system or apparatus proceeded by “comprises . . . a” does not, without more constraints, preclude the existence of other elements or additional elements in the device or system or apparatus.

In the following detailed description of the embodiments of the disclosure, reference is made to the accompanying drawings that form a part hereof, and in which are shown by way of illustration specific embodiments in which the disclosure may be practiced. These embodiments are described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

Amplifiers, such as electrical signal/power amplifier are generally made from electronic devices. However, such amplifiers cannot achieve performance corresponding to thermal noise level and hence have limited noise performance.

Micro-Electromechanical (MEM) devices offer miniaturized solutions and are generally used in various applications, for example, but not limited to, inertial sensors- such as accelerometers and gyroscopes, microfluidics devices- such as ink-jet printers, mass flow sensors, and bio-chemical analysis devices, optical applications—such as displays and optical switches, pressure measurement devices used in medical, automotive, and industrial fields, Radio-Frequency (RF) devices- including switches, radar components, and RF components integrated in laptop computers and cell-phones, micro-relays, disk-heads, and the like. Transducing and actuation/sensing in such devices may be performed using a variety of modes, including, but not limited to, piezoelectric, piezo-resistive, electro-static, electro-thermal, electro-magnetic, and optical methods. The most widely implemented transduction method involves capacitive actuation and sensing. Capacitive transductions offer benefits of cost-effective fabrication, minimal power consumption, low noise, negligible impact on quality factor and low temperature coefficients.

As per the existing techniques, MEM and Nanoelectromechanical (NEM) resonator systems have been considered as passive filter devices. The existing equivalent circuit models for the resonators, such as Butterworth Van-Dyke model, Mason's model, and myriad adaptations of such models, do not bring out active nature or possibility of achievable electrical signal/power amplification, since these models are implemented under the assumption that the resonator is a passive device. However, the present subject matter provides techniques to implement the resonators as amplifiers. As per the present subject matter, to show/explain the possibility of amplification a dependent voltage source is introduced in the new electrical circuit equivalent for the combined system of the resonator and the sensing unit. The source of energy required for amplification is also introduced in the equivalent circuit model of the entire/complete system.

In general, amplification in electrical domain may be categorized as 1) signal amplification, 2) power amplification. While signal amplification is also possible in single signal-source electrical-network, power amplification requires additional power-source, usually a Direct Current (DC) source. The present subject matter presents required equations and circuit schematics for implementing both signal and power amplification using a system of electrostatically sensed micro/nano-electromechanical resonators. Further, as per some of the example embodiments of the present subject matter, voltage output of k different resonators is coupled to a single electrically floating sense-electrode. As per the present subject matter, the use of voltage-sensing at sensing electrode in MEM device enables realization of a purely movable-structure based amplifier. Said amplifier, when implemented as per the present subject matter has a potential of being implemented for timing reference devices and applications, RF based engineering solutions and various other applications.

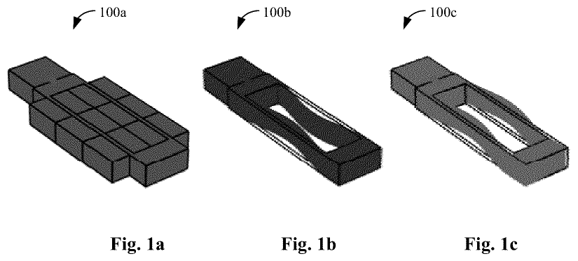

FIGS. 1a-1c illustrate schematic diagrams of DETF resonator. FIG. 1a illustrates schematic diagram 100a of a Double Ended Tuning Fork (DETF) resonator used as an exemplary implementation of the present subject matter. FIG. 1b illustrates a schematic diagram 100b showing a first in-plane resonant mode of the DETF resonator used as an exemplary implementation of the present subject matter. FIG. 1c illustrates a schematic diagram 100c showing a second in-plane resonant mode of the DETF resonator used as an exemplary implementation of the present subject matter. In the subsequent sections, a mathematical model for voltage response is illustrated at the sensing electrode (also referred hereinafter and in figures as sense electrode) for the voltage sensing methodologies. The present disclosure describes the exemplary embodiments with respect to a DETF. However, a person skilled in the art will appreciate that similar, analogous, and/or equivalent techniques may also be implemented using any of the capacitively-transduced micro- and nano-mechanical resonators (also referred hereinafter and in the figures as a resonator and a resonator system).

The resonator, as per the present subject matter, may be a mechanical resonator, representative of a device capable of transforming energy from a potential energy into a kinetic energy and transforming the kinetic energy into the potential energy in an oscillatory manner/fashion. Herein, in the context of the present subject matter, the term ‘resonator’ is also interchangeably used to refer to ‘the resonator system’. For example, the resonator system comprises the resonator and one or more components and/or electrodes that aid in capacitive transduction of the mechanical resonator. For example, the one or more components and/or electrodes are made to resonate with the input electrical signals. Examples of the one or more components and/or electrodes may include, but are not limited to, actuation electrodes, sensing electrodes, tuning electrodes, and biasing electrodes. A person skilled in the art will appreciate that the resonator system, in accordance with various embodiments of the present subject matter, may include other components, electrodes, and/or sub-systems which are necessarily required to bias, actuate, and sense a resonant behavior. In the present disclosure, the objective in which the term ‘the resonator’ is used can be inferred from the context in which it is used.

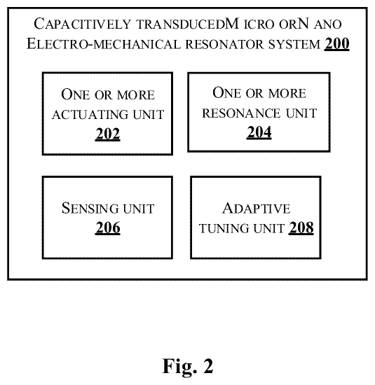

FIG. 2 illustrates a block diagram of a capacitively transduced Micro or Nano Electro-mechanical resonator system 200, in accordance with an embodiment of the present disclosure. The capacitively transduced Micro or Nano Electro-mechanical resonator system 200 (also referred hereinafter as a resonator system 200 for the sake of brevity) comprises one or more actuating units 202, one or more resonance units 204, a sensing unit 206, and an adaptive tuning unit 208.

The one or more actuating units 202 may be configured to generate one or more actuating signals based on one or more input signals. In an example, the one or more actuating units 202 may generate the one or more actuating signals for providing an input stimulus that may initiate mechanical vibrations in the resonator structure. Such vibrations are crucial for the resonator system 200 to perform associated sensing or timing functions. For example, the one or more actuating signals may excite the resonator system 200 into associated fundamental or desired vibrational mode. Such excitation may help in maintaining a stable oscillations at a resonant frequency of the resonator system 200. Therefore, such excitations may enable conversion of physical parameters into measurable frequency shifts. For example, the physical parameters may include, without limitation, pressure, acceleration, and/or temperature. The one or more resonance units 204 is coupled to the one or more actuating units 202. Each of the one or more resonance units 204 may be configured to resonate in response to the one or more actuating signals based on a value of capacitance associated with each of the respective one or more resonance units 204.

The sensing unit 206 may be capacitively coupled to the one or more resonance units 204. The sensing unit 206 may be configured to sense one or more capacitance component, associated with the sensing unit 206, in response to one or more of generation of the one or more actuating signals and resonation of the one or more of resonance units 204.

In an embodiment, the sensing unit comprises one or more sensing electrodes. In an embodiment, the sensing amplifier is a differential amplifier. In a non-limiting embodiment, the amplified output signal is one of an amplified voltage signal and a phase shifted amplified signal.

In an embodiment, the sensing unit 206 may be further configured to sense the resonation of the one or more resonance units 204. In an exemplary embodiment, the capacitance component may further relate to resultant charges associated with the one or more of generation and resonation of the one or more actuating signals. In a non-limiting embodiment, the capacitance component is associated with one of a parasitic capacitance, an intended capacitance, or a stray capacitance. For example, the capacitance component may be a component related to one of a parasitic capacitance, an intended capacitance, or a stray capacitance. For example, the intended capacitance may be a target or design-dependent capacitance related to the resonator system.

In an embodiment, in response to one or more of generation of the one or more actuating signals and resonation of the one or more of resonance units, the sensing unit 206 is configured to sense an output signal. The output signal may comprise summation of one or more of resonated signals from the one or more of resonance units.

The adaptive tuning unit 208 may be coupled to the sensing unit 206. The adaptive tuning unit 208 may be configured to generate a tuning signal to tune, based on at least one of the one or more capacitance component and the resonation of the one or more of resonance units 204, respective resonant frequency of each of the one or more of resonance units 204.

In an embodiment, the adaptive tuning unit 208 may be coupled to the sensing unit 206. The adaptive tuning unit 208 may be configured to selectively generate, based on the tuning, one or more amplified output signals.

In an embodiment, the sensing unit 206 may be coupled to a Direct Current (DC) bias voltage generation unit (not shown). The DC bias voltage generation unit may be configured to generate a DC bias voltage. The DC bias voltage may be transferred to the adaptive tuning unit 208. In an example, the adaptive tuning unit 208 may be configured to generate the tuning signal based on the DC bias voltage. The tuning signal may be generated to tune the respective resonant frequency of each of the one or more of resonance units 204.

In an embodiment, the sensing unit 206 may be coupled to an Alternating Current (AC) bias voltage generation unit. The AC bias voltage generation unit may be configured to generate an AC bias voltage. The AC bias voltage may be transferred to the adaptive tuning unit 208. In an embodiment, the adaptive tuning unit 208 may be configured to generate the tuning signal based on the AC bias voltage. The offset signal may be generated to tuning signal to tune the respective resonant frequency of each of the one or more of resonance units 204.

In an exemplary embodiment, to tune the respective resonant frequency of each of the one or more of resonance units 204, the adaptive tuning unit 208 may be configured to apply a Direct Current (DC) bias voltage to one or more electromechanical elements of each of the one or more of resonance units 204 to shift the phase of the one or more input signals. Further, the adaptive tuning unit 208 may be configured to generate an output value by adding the one or more of phase shifted input signals.

In an exemplary embodiment, one or more structural parameters of the resonator system 200 are configured to be dynamically modified. In an example, the adaptive tuning unit 208 is further configured to generate an output value by adding the one or more amplified output signals pertaining to the dynamically modified one or more structural parameters.

In an example, the one or more actuating units 202 are configured to receive one or more of input signals. The adaptive tuning unit 208 is configured to shift a phase of each of the one or more of input signals to a predetermined phase angle. Further, adaptive tuning unit 208 is configured to generate an output value by adding the one or more of phase shifted input signals.

In an example, to tune the respective resonant frequency of each of the one or more of resonance units, the adaptive tuning unit 208 may be configured to apply individual Direct Current (DC) bias voltage to one or more electromechanical elements of each of the one or more of resonance units to shift the phase of each of the one or more of phase shifted input signals.

In an exemplary embodiment, the resonator system 200 further comprises a phase shifting element comprising a low pass filter, configured to shift the phase of the detected and amplified signal by a value in a range of 45 to 135 degrees or −45 to −135 degrees.

In a non-limiting embodiment, the one or more input signals is an input voltage signal, and wherein, to tune the respective resonant frequency of each of the one or more of resonance units, the adaptive tuning unit is configured to apply a Direct Current (DC) bias voltage to one or more electromechanical elements of each of the one or more of resonance units to amplify a voltage component of the input voltage signal.

In a non-limiting embodiment, the one or more input signals is an input voltage signal. The one or more actuating units 202 may be configured to receive one or more of input voltage signals. The adaptive tuning unit 208 may be configured to amplify a voltage component of each of the one or more of input voltage signals to a predetermined voltage. Further, the adaptive tuning unit 208 may be configured to generate an output value by adding the one or more of amplified input voltage signals.

In a non-limiting embodiment, the one or more input signals is an input voltage signal. In an example, to tune the respective resonant frequency of each of the one or more of resonance units 204, the adaptive tuning unit 208 may be configured to apply individual Direct Current (DC) bias voltage to one or more electromechanical elements of each of the one or more of resonance units to amplify the voltage component of each of the one or more of input voltage signals. In an example, the sensing amplifier may be a differential amplifier. In an embodiment, the resonator system 200 comprises a sensing amplifier (not shown in FIG. 2) and a Low Pass Filter (LPF) (not shown in FIG. 2). For example, the sensing amplifier may be coupled to the sensing unit 206. The sensing amplifier may be configured to amplify an output signal received from the sensing unit 206. In some embodiments, the Low Pass Filter (LPF) may be coupled to the sensing amplifier. The LPF may be configured to attenuate high-frequency noise components above a predetermined cutoff frequency, from the amplified output signal received from the sensing amplifier.

The resonator system 200 may further include a signal processing element (not shown in FIG. 2). The signal processing element may be coupled to the LPF. The signal processing element may be configured to process a filtered signal received from the LPF. Further, the signal processing element may be configured to transfer the processed signal to the adaptive tuning unit 208. In an example, the adaptive tuning unit 208 may be configured to tune the respective resonant frequency of each of the one or more of resonance units 204. In an embodiment, the signal processing element may be further configured to receive one or more input signals comprising the filtered signal, received from the LPF, and a reference voltage. The signal processing element may be further configured to process the one or more input signals.

The signal processing element may be further configured to transfer the processed input signal to the adaptive tuning unit 208. The adaptive tuning unit 208 may be configured to generate, based on the processed input signal, the tuning signal to tune the respective resonant frequency of each of the one or more of resonance units 204. In an embodiment, the resonator system 200 comprises an enclosure (not shown in FIG. 1) for enclosing at least one of the one or more actuating units 202, the one or more resonance units 204, the sensing unit 206, and the adaptive tuning unit 208.

A person skilled in the art will appreciate that the present disclosure is applicable to any type of suitable Micro or Nano Electro-mechanical resonator system other than the above-mentioned resonator system.

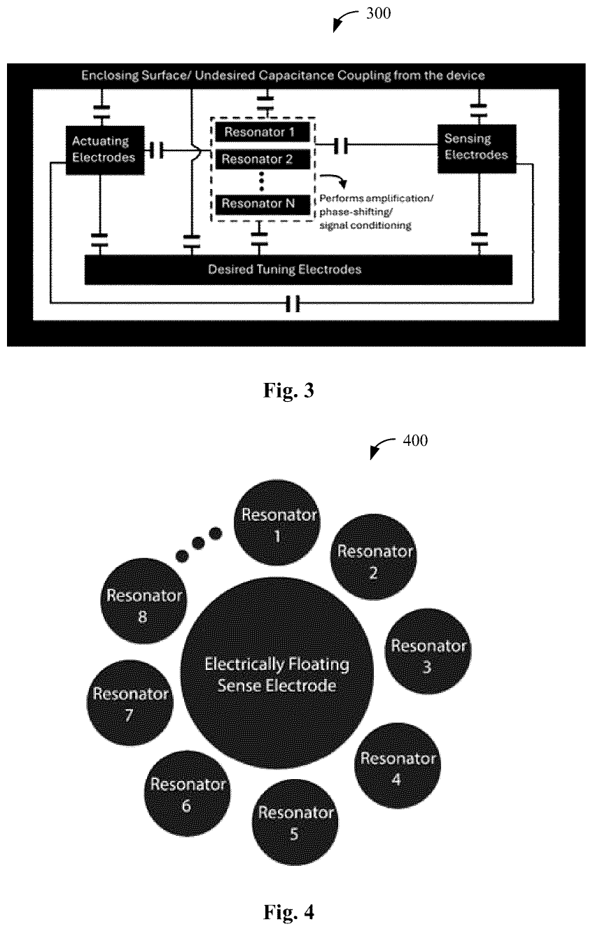

FIG. 3 illustrates a schematic diagram 300 of a capacitively transduced MEM resonator system, in accordance with an embodiment of the present disclosure. In an embodiment, the capacitively transduced MEM resonator system is a capacitive air/vacuum/dielectric-gap-closing MEM resonator system. The capacitively transduced MEM resonator system may also be referred hereinafter, in the present disclosure, as a MEM resonator system or a MEM device. In some embodiments, the capacitive air/vacuum/dielectric-gap-closing MEM resonator system includes an actuation electrode (also referred hereinafter and in figures as actuating electrode), a plurality of resonators or a moving beams (illustrated in FIG. 3 as resonator 1—resonator N), sensing electrodes, designed tuning electrodes, electrically-floating electrodes, and an enclosing surface. The enclosing surface may be composed of same or different material at different spatial positions around the resonator system. The MEM device may implement voltage-sensing on electrically-floating electrical node, such as resonator, using bias-tuning/compensating/gate/secondary electrodes. In some embodiments, the bias-tuning/compensating/gate/secondary electrode may be capacitively coupled with the electrically-floating electrode. The control signal for the bias-tuning/compensating/gate/secondary electrode may be obtained using a feedback circuit (not shown in the figures).

FIG. 4 illustrates a schematic diagram 400 of a system of electrostatically sensed micro/nano-electromechanical resonators, in accordance with an embodiment of the present disclosure. In accordance with FIG. 4, voltage output of k different resonators with different resonant frequencies with different biasing voltages is coupled to a single electrically floating sense-electrode.

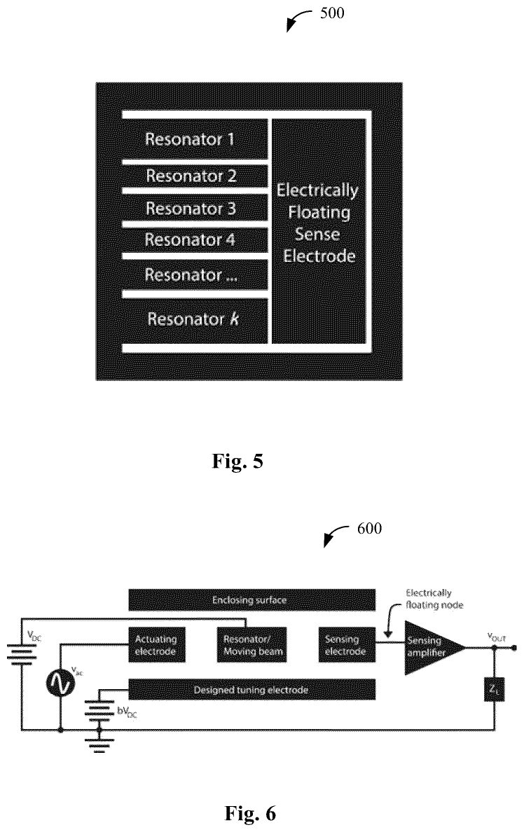

FIG. 5 illustrates a schematic diagram 500 of an example system where voltage output of k resonators is collected at the same sensing electrode, in accordance with some embodiments of the present disclosure. In accordance with FIG. 5, in some embodiments, the k resonators may be operating at same or different resonant frequencies. Each resonator may be actuated through separate input electrodes via electrostatic means so that the output voltage measured at the electrically floating sensing electrode is a weighted sum of all the input voltages.

FIG. 6. illustrates a circuit schematic 600 of a capacitively transduced MEM resonator system for floating voltage sensing, in accordance with some embodiments of the present disclosure. As illustrated in FIG. 6, in some embodiments, the capacitively transduced MEM resonator system comprises an actuation electrode, a resonator or a moving beam, a sensing electrode, a sensing amplifier, a designed tuning electrode, electrically-floating node, and an enclosing surface. The actuation electrode, the resonator or the moving beam, the sensing electrode, the designed tuning electrode, the electrically-floating node, and the enclosing surface of FIG. 6, are similar, in terms of function and structure, to the actuation electrode, the resonator or the moving beam, the sensing electrode, the designed tuning electrode, the electrically-floating node, and the enclosing surface of FIG. 3.

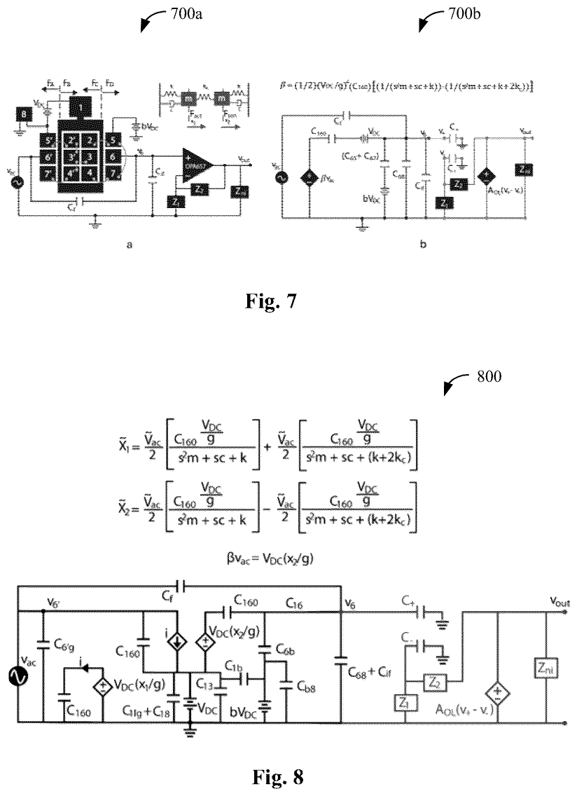

FIG. 7 illustrates (a) coupled spring-mass system equivalent 700a of the DETF resonator and its circuit schematic 700b when a voltage signal is measured at the sensing electrode and (b) equivalent circuit of the electro-mechanical system at output node depicted in (a).

As per the present subject matter, the device topology, as illustrated in FIG. 7, provides application of a tuning voltage whose impact can not be captured using existing/standard Mason model or BVD equivalent circuit models. Hence, the present subject matter depicts a new equivalent circuit models for the combined system of resonator and the sensing unit. The resonator at the sensing electrode is modelled as a voltage-controlled voltage source, whose gain, β, depends on the electromechanical transduction of the MEM device when terminated in the sensing amplifier. This gain β can be tuned using various parameters as described in later section. The output voltage of the dependent source, βv_{ac}, divides across the potential divider formed by the capacitance between the resonator and the sensing electrode of the MEM device and the input impedance of an amplifier. Phase and magnitude of dependent source, βv_{ac}, varies with the frequency, as illustrated in the equation written in FIG. 7. In an embodiment, the phase or magnitude may be affected by the choice of the sensing amplifier used in the device topology.

In some embodiments, equivalent circuit of a resonator and VA system derived in terms of dependent source may account for additional DC sources connected to the resonator and enables calculation of output impedance of the resonator when terminated in a particular configuration of the sensing amplifier. Furthermore, it is possible to increase the gain of the resonator itself by increasing the β for the device. This may be achieved by a combination of increase in V_{DC}, reduction in gap (g), increase of area of transduction to increase C₁₆₀, increasing quality factor and reducing stiffness of the resonant structure. Thus, with the voltage sensing approach, it is possible to get an overall gain, vₒᵤₜ/v_{ac}, greater than 1 by appropriately designing the system such that βv_{ac}*Cᵣ/(Cᵣ+C_{if})≥1. Since the ratio Cᵣ/(C, +C_{if}) may approach 1 as C_{if} is reduced by better integration of the resonator and the amplifier and the β may be increased substantially as well by appropriate design choices, it is possible to achieve the overall gain, vₒᵤₜ/v_{ac}>1. In other words, the voltage measurement topology, as per the present subject matter acts as a voltage amplifier even with sensing unit being a pure voltage buffer configuration. For electrical power amplification, resonator must be terminated in a resistor, and the mathematical expressions change accordingly. The condition for power amplification has been derived for an example case and can be extended to any other related case, in general.

FIG. 8 illustrates an equivalent circuit diagram 800 of a combined system of a resonator and a sense amplifier/buffer when transduced actuation and sensing capacitances are viewed as dependent sources, in accordance with some embodiments of the present disclosure. In an embodiment, configuration, as illustrated in FIG. 8, can specifically be used to derive mathematical relations for signal amplification. In an example, the combined system may include the resonator and a voltage amplifier. In accordance with FIG. 8, in some embodiments, the dependent current source corresponding to the actuation beam models the effect of varying input transduced capacitance and the dependent voltage source corresponding to the sensing beam models the effect of the change in output transduced capacitance.

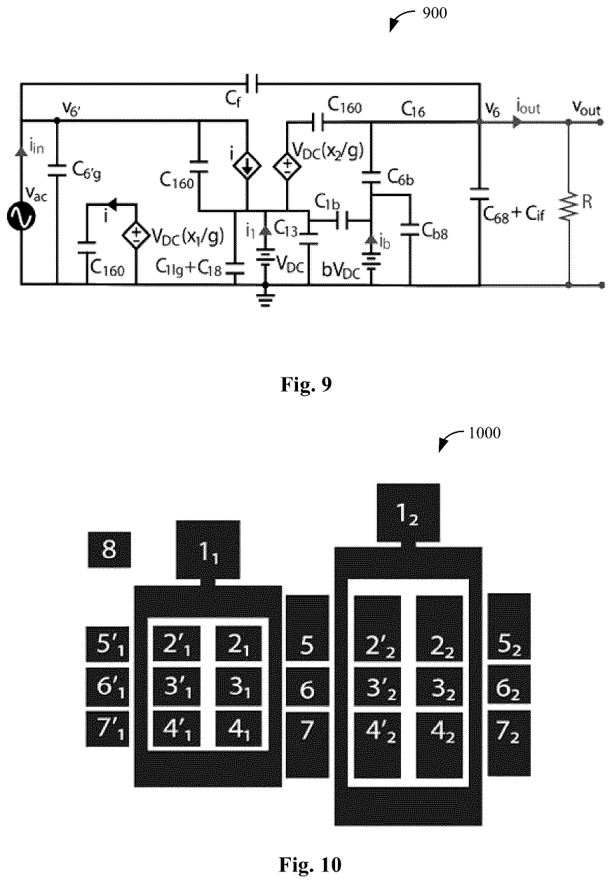

FIG. 9 illustrates an equivalent circuit diagram 900 of a combined system of a resonator and a load-resistor, when transduced actuation and sensing capacitances are viewed as dependent sources, in accordance with some embodiments of the present disclosure. In an embodiment, configuration, as illustrated in FIG. 9, can specifically be used to derive mathematical relations for electrical power amplification or signal amplification in case of resistive loading. In accordance with FIG. 9, in some embodiments the dependent current source corresponding to the actuation beam models the effect of varying input transduced capacitance and the dependent voltage source corresponding to the sensing beam models the effect of the change in output transduced capacitance. In an embodiment, while capacitive loading of the resonator may give signal amplification, the concept of power amplification is more relevant for the case of resistive loading as illustrated in FIG. 9. Detailed analysis reveals the range of wRCₜₒₜₐₗ for which power amplification is achieved with the resonating structure.

FIG. 10 illustrates circuit schematic 1000 of an example system where voltage output of two resonators is collected at the same electrically floating sensing electrode, in accordance with some embodiments of the present disclosure. In accordance with FIG. 10, in some embodiments, the two resonators may be operating at same or different resonant frequencies. For example, these two resonators can be operated in such a way that the electrode 6₁′ is the actuation electrode for the DETF drawn on the left side and electrode 6₂ is the actuation electrode for the DETF drawn on the right-hand side. Electrode 6 forms the electrically floating sensing electrode and 1₁ and 1₂ can be given the bias supplies for two DETFs presented. Remaining electrodes can be grounded, left open or connected to DC supplies of choice as required by the application and intended use of the entire device.

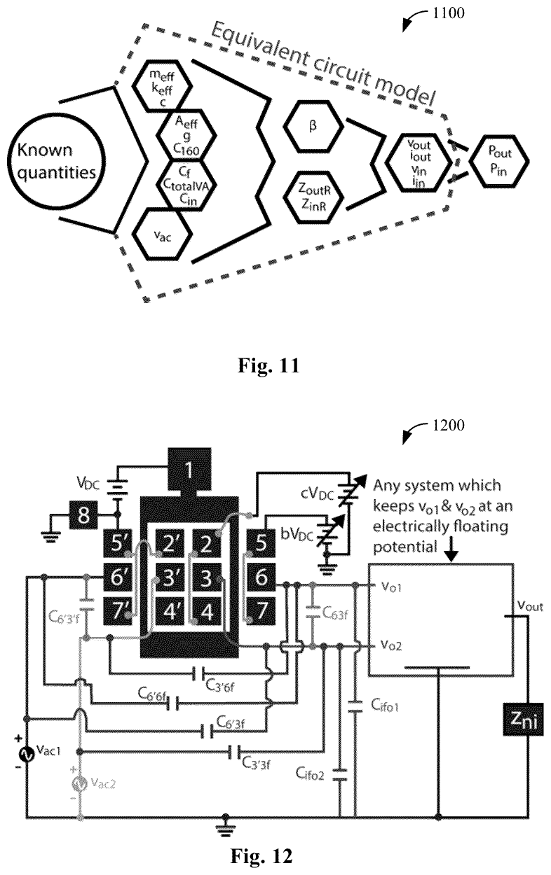

FIG. 11 illustrates a schematic representation 1100 of parameters required for designing a complete equivalent circuit diagram of an exemplary system of electrostatically sensed micro/nano-electromechanical resonators, in accordance with some embodiments of the present disclosure. As illustrated in FIG. 11, parameters to be estimated for implementing the equivalent circuit diagram of an exemplary system of electrostatically sensed micro/nano-electromechanical resonators are divided in four levels. A first level includes-m_{eff}, k_{eff}, c, A_{eff}, g,C₁₆₀ C_{f}, C_{totalVA}, Cᵢₙ, v_{ac} which are either known by design or may be estimated from measurements. Upon obtaining or with the knowledge of parameters of level 1, mentioned above, parameters of a second level which include—β, Z_{outR}, Z_{inR} may be estimated. Further, equivalent circuit diagram completes with the knowledge of parameters of a third level which includes—vₒᵤₜ, iₒᵤₜ, vᵢₙ, iᵢₙ which may be estimated from the knowledge of the first level and the second level of parameters shown in FIG. 11. Furthermore, parameters of a fourth level which includes—Pₒᵤₜ, and Pᵢₙ may be calculated based on the respective parameters related to the first level, the second level, and the third level.

The respective parameters relating to the first, second, third, and fourth levels are presented in the following equations.

$$\begin{matrix}Effective mass equation & \\ {m}_{eff} = \frac{2 ϵ {A}_{eff}}{{g}^{3}} \frac{( {V}_{DC \_ 2}^{2} - {V}_{{DC}_{1}}^{2} )}{( {w}_{1}^{2} - {w}_{2}^{2} )} & Equation 1\end{matrix}$$

where:
m_{eff} is the effective mass of the resonator modelled for equivalent spring-mass system
ϵ is the permittivity of the material which forms the actuation and sensing capacitance
g is nominal gap between the resonator and the actuation/sensing electrodes
A_{eff} is the effective area of the resonator which forms parallel plate capacitance with the actuation/sensing electrode in the exemplary case and forms the assumed capacitance in the general case
V_{DC_n} is the bias voltage of the resonator for collecting data at nth applied DC voltage of the resonator
wₙ is the resonant frequency of the resonator at nth DC bias voltage V_{DC_n}

$$\begin{matrix}Total effective - stiffness equation & \\ {k}_{eff \_ 1} = {m}_{eff} {w}_{1}^{2} & Equation 2\end{matrix}$$

where:
k_{eff_n} is the effective stiffness for the equivalent spring mass system at bias voltage
V_{DC_n}. This term includes the effect of bias voltage of the resonator on the effective mechanical stiffness of the resonator.
m_{eff} is the effective mass of the resonator modelled for equivalent spring-mass system
wₙ is the resonant frequency of the resonator at nth DC bias voltage V_{DC_n}

$$\begin{matrix}Effective mechanical - stiffness equation & \\ {k}_{mech} = {k}_{eff \_ 1} + \frac{2 ϵ {A}_{eff} {V}_{DC \_ 1}^{2}}{{g}^{3}} & Equation 3\end{matrix}$$

where:
k_{mech} is the effective stiffness of the resonator for the equivalent spring mass system when the effect of DC bias voltage of the resonator on the effective stiffness is not taken into account
k_{eff_1} is the effective stiffness for the equivalent spring mass system at bias voltage V_{DC_1}. This term includes the effect of bias voltage of the resonator on the effective mechanical stiffness of the resonator.
V_{DC_n} is the bias voltage of the resonator for collecting data at nth operating DC voltage of the resonator
ϵ is the permittivity of the material which forms the actuation and sensing capacitance
g is fabricated gap between the resonator and the actuation/sensing electrodes
A_{eff} is the effective area of the resonator which forms parallel plate capacitance with the actuation/sensing electrode in the exemplary case and forms the assumed capacitance in the general case

$$\begin{matrix}Effective damping equation & \\ {c}_{1} = \frac{{w}_{1} * {m}_{eff}}{Q} & Equation 4\end{matrix}$$

where:
cₙ is the effective damping of the equivalent spring-mass-damper system at resonator when the bias voltage is V_{DC_n}
Q is the quality factor of the resonator
m_{eff} is the effective mass of the resonator modelled for equivalent spring-mass system
wₙ is the resonant frequency of the resonator at nth DC bias voltage V_{DC_n}

$$\begin{matrix}\begin{matrix}Equation for nominal gap in terms of \\ measurable and calculable quantities\end{matrix} & \\ g = \frac{1}{4} [ \frac{{( ϵ {A}_{eff} )}^{1}}{{C}_{totalVA}} \frac{{V}_{DC \_ 3}^{2}}{1} ] \frac{{A}_{CL} * Q}{{w}_{3}^{2} * {ψ}_{3}} \frac{( {w}_{1}^{2} - {w}_{2}^{2} )}{( {V}_{DC \_ 2}^{2} - {V}_{{DC}_{1}}^{2} )} & Equation 5\end{matrix}$$

where:
ϵ is the permittivity of the material which forms the actuation and sensing capacitance
g is fabricated gap between the resonator and the actuation/sensing electrodes
A_{eff} is the effective area of the resonator which forms parallel plate capacitance with the actuation/sensing electrode in the exemplary case and forms the assumed capacitance in the general case
V_{DC_n} is the bias voltage of the resonator for collecting data at nth operating DC voltage of the resonator
wₙ is the resonant frequency of the resonator at nth DC bias voltage V_{DC_n}
Q is the quality factor of the resonator
A_{CL} is the closed loop gain of the amplifier being used as sensing unit
C_{totalVA} is the sum of all capacitances which have output node/electrode of the resonator as one of their terminals, when the sensing electrode of the resonator terminated in the VA (Voltage Amplifier)
ψₙ is magnitude of (Sigₘₑₐₛ_{ₜₒₜₐₗ}−Sigₘₑₐₛ_{_{feed}}), where Sigₘₑₐₛ_{ₜₒₜₐₗ} is the phasor of total signal at the resonant frequency in phasor form and the Sigₘₑₐₛ_{_{feed}} is the phasor of the feedthrough signal at the resonant frequency with DC bias voltage turned to 0V.

$$\begin{matrix}Nominal transduced capacitance equation & \\ {C}_{160} = \frac{{ϵ}_{0} {A}_{eff}}{g} & Equation 6\end{matrix}$$

where:
C₁₆₀ is the nominal actuation/sensing capacitance when the displacement of the resonator is 0 μm.
ϵ₀ is the permittivity of the free space
g is fabricated gap between the resonator and the actuation/sensing electrodes

$$\begin{matrix}Equation for feedthrough - capacitance calculation in terms of measurements performed & \\ {C}_{f} = \frac{Gain at feedthrough level at frequency w with TIA ( V / V )}{{wR}_{fb}} & Equation 7\end{matrix}$$

where:
C_{f} is the feedthrough capacitance of the system
w is the frequency at which the gain is measured for performing the above calculation
R_{fb} is the feedback capacitance of the feedback network if the TIA used

$$\begin{matrix}Equation for {C}_{totalVA} in terms of measured quantities & \\ {C}_{totalVA} = \frac{{C}_{f}}{Gain at feedthrough level at frequency w with VA ( V / V )} & Equation 8\end{matrix}$$

where:
C_{totalVA} is the sum of all capacitances which have output node/electrode of the resonator as one of their terminals, when the sensing electrode of the resonator terminated in the VA (Voltage Amplifier)
C_{f} is the feedthrough capacitance of the system

$${C}_{in} = known by symmerty or measurements \qquad Equation 9$$

where:
Cᵢₙ is the input capacitance of the resonator

$$\begin{matrix}\begin{matrix}Equation for β at resonance in terms of \\ measured and supplied quantities\end{matrix} & \\ {β}_{res 1} = \frac{Q}{4} {( \frac{{V}_{DC 1}}{{w}_{1}} )}^{2} ( \frac{{w}_{1}^{2} - {w}_{2}^{2}}{{V}_{DC 2}^{2} - {V}_{DC 1}^{2}} ) & Equation 10\end{matrix}$$

where:
βᵣₑₛ₁ is gain coefficient of the dependent voltage-controlled voltage-source when the applied DC voltage is V_{DC1}
Q is the quality factor of the resonator
V_{DC_n} is the bias voltage of the resonator for collecting data at nth operating DC voltage of the resonator
wₙ is the resonant frequency of the resonator at nth DC bias voltage V_{DC_n}

$$\begin{matrix}\begin{matrix}Equation for β at resonance in terms of \\ estimated and known quantities\end{matrix} & \\ {β}_{res 1} = \frac{Q}{2} \frac{{C}_{160}}{{g}^{2}} \frac{{V}_{DC 1}^{2}}{{k}_{mech}} & Equation 11\end{matrix}$$

where:
βᵣₑₛ₁ is gain coefficient of the dependent voltage-controlled voltage-source at the resonance frequency when the resonator is terminated in sensing voltage amplifier (VA) and the applied DC voltage is V_{DC1}
Q is the quality factor of the resonator
V_{DC_n} is the bias voltage of the resonator for collecting data at nth operating DC voltage of the resonator
k_{mech} is the effective stiffness of the resonator for the equivalent spring mass system when the effect of DC bias voltage of the resonator on the effective stiffness is not accounted for
C₁₆₀ is the nominal actuation/sensing capacitance when the displacement of the resonator is 0 μm.
g is fabricated gap between the resonator and the actuation/sensing electrodes

$${Z}_{outR} , {Z}_{inR} , {v}_{out} , {i}_{out} , {v}_{in} , {i}_{in} , {P}_{out} , {P}_{in} = from equivalent circuit model \qquad Equation 12$$

where:
Z_{outR} is the output impedance of the resonator when the sensing electrode of the resonator is terminated in a resistor
Z_{inR} is the input impedance of the resonator when the sensing electrode of the resonator is terminated in a resistor
vₒᵤₜ is the output voltage of the combined system of the resonator and sensing unit or the resonator and the loading resistor/element
iₒᵤₜ is the current that flows in of the node where vₒᵤₜ is measured, like in the loading resistor or loading impedance Zₙᵢ
vᵢₙ is the ac voltage input to the resonator
iᵢₙ is the current that flows from the vᵢₙ
Pₒᵤₜ is the active power output from the vₒᵤₜ node
Pᵢₙ is the active power input from the vᵢₙ node

$$Equation for displacement of actuation - beam in terms of spring , mass , damping , applied voltages , and involved capacitances$$

$${\tilde{X}}_{1} = \frac{1}{2} [ \frac{{C}_{160} \frac{{V}_{D C}}{g} {\tilde{V}}_{a c}}{{s}^{2} {m}_{eff} + s c + {k}_{eff}} ] [ 1 - \frac{{C}_{f}}{{C}_{totalVA}} ] + \frac{1}{2} [ \frac{{C}_{160} \frac{{V}_{D C}}{g} {\tilde{V}}_{a c}}{{s}^{2} {m}_{eff} + s c + ( {k}_{eff} + 2 {k}_{c} )} ] [ 1 + \frac{{C}_{f}}{{C}_{totalVA}} ] \qquad Equation 13$$

where:
\tilde{X}₁ is the Laplace form of the displacement of the actuation arm of the exemplary DETF
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
\tilde{V}^{ac} is the ac voltage applied to the actuation electrode in Laplace domain
C_{f} is the feedthrough capacitance of the system
C_{totalVA} is the sum of all capacitances which have output node/electrode of the resonator as one of their terminals, when the sensing electrode of the resonator terminated in the VA (Voltage Amplifier)
m_{eff} is the effective mass of the resonator modelled for equivalent spring-mass system
c is the effective damping of the equivalent spring-mass system
k_{eff} is the effective stiffness of the equivalent spring mass system
k_{c} is the effective coupling stiffness of the equivalent coupled spring-mass system
s is the complex frequency variable in Laplace domain

$$Equation for displacement of sensing - beam in terms of spring , mass , damping , applied voltages , and involved capacitances$$

$${\tilde{X}}_{2} = \frac{1}{2} [ \frac{{C}_{I 60} \frac{{V}_{D C}}{g} {\tilde{V}}_{a c}}{{s}^{2} {m}_{eff} + s c + {k}_{eff}} ] [ 1 - \frac{{C}_{f}}{{C}_{totalVA}} ] - \frac{1}{2} [ \frac{{C}_{I 60} \frac{{V}_{D C}}{g} {\tilde{V}}_{a c}}{{s}^{2} {m}_{eff} + s c + ( {k}_{eff} + 2 {k}_{c} )} ] [ 1 + \frac{{C}_{f}}{{C}_{totalVA}} ] \qquad Equation 14$$

where:
\tilde{X}₂ is the Laplace form of the displacement of the sensed arm of the exemplary DETF
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
\tilde{V}^{ac} is the ac voltage applied to the actuation electrode in Laplace domain
C_{f} is the feedthrough capacitance of the system
C_{totalVA} is the sum of all capacitances which have output node/electrode of the resonator as one of their terminals, when the sensing electrode of the resonator terminated in the VA (Voltage Amplifier)
m_{eff} is the effective mass of the resonator modelled for equivalent spring-mass system
c is the effective damping of the equivalent spring-mass system
k_{eff} is the effective stiffness of the equivalent spring mass system
k_{c} is the effective coupling stiffness of the equivalent coupled spring-mass system
s is the complex frequency variable in Laplace domain

$$Equation for voltage at sensing electrode in terms of spring , mass , damping , applied voltages , and involved capacitances$$

$${\tilde{V}}_{out} = \frac{{C}_{f}}{{c}_{totalVA}} {\tilde{V}}_{a c} + \frac{{\tilde{V}}_{a c}}{2} [ \frac{{C}_{160}}{{C}_{totalVA}} \frac{{V}_{D C}}{g} ] [ ( \frac{{C}_{160} \frac{{V}_{D C}}{g}}{{s}^{2} {m}_{eff} + s c + {k}_{eff}} ) ( 1 - \frac{{C}_{f}}{{C}_{totalVA}} ) - ( \frac{{C}_{160} \frac{{V}_{D C}}{g}}{{s}^{2} {m}_{eff} + s c + ( {k}_{eff} + 2 {k}_{c} )} ) ( 1 + \frac{{C}_{f}}{{C}_{totalVA}} ) ] \qquad Equation 15$$

where:
\tilde{V}ₒᵤₜ is the Laplace form of the output voltage of the VA (voltage amplifier)
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
\tilde{V}^{ac} is the ac voltage applied to the actuation electrode in Laplace domain
C_{f} is the feedthrough capacitance of the system
C_{totalVA} is the sum of all capacitances which have output node/electrode of the resonator as one of their terminals, when the sensing electrode of the resonator terminated in the VA (Voltage Amplifier)
m_{eff} is the effective mass of the resonator modelled for equivalent spring-mass system
c is the effective damping of the equivalent spring-mass system
k_{eff} is the effective stiffness of the equivalent spring mass system
k_{c} is the effective coupling stiffness of the equivalent coupled spring-mass system
s is the complex frequency variable in Laplace domain

$$Equation for total {I}_{out} and {I}_{out} at resonance as marked in FIG . 9$$

$${\tilde{I}}_{out} = \frac{{\tilde{V}}_{out}}{R} ; {\tilde{I}}_{outres} = \frac{{\tilde{V}}_{outres}}{R} \qquad Equation 16$$

where:
Ĩₒᵤₜ is the Laplace form of the output current iₒᵤₜ, flowing in the load resistor R in the FIG. 9
\tilde{V}ₒᵤₜ is the Laplace form of the output voltage across the load resistor R in the FIG. 9
Ĩₒᵤₜᵣₑₛ is the Laplace form of the output current iₒᵤₜ, at resonant frequency, flowing in the load resistor R in the FIG. 9
\tilde{V}ₒᵤₜᵣₑₛ is the Laplace form of the output voltage at resonant frequency across the load resistor R in the FIG. 9
R is the load resistor in FIG. 9

$$Equation for {I}_{out} at resonance in terms of measured and estimated \\ quantities$$

$${\tilde{I}}_{outres} = \frac{1}{R} \frac{{C}_{f}}{{C}_{totalR}} {\tilde{V}}_{a c} + {\frac{{\tilde{V}}_{a c}}{2 c} [ {C}_{160} \frac{{V}_{D C}}{g} ]}^{2} [ \frac{1}{{sRC}_{totalR}} ] \qquad Equation 17$$

where:
Ĩₒᵤₜᵣₑₛ is the Laplace form of the output current iₒᵤₜ, at resonant frequency, flowing in the load resistor R in the FIG. 9
C_{f} is the feedthrough capacitance of the system
C_{totalR} is the sum of all capacitances which have output node/electrode of the resonator as one of their terminals, when the sensing electrode of the resonator terminated in a resistor as in FIG. 9
R is the load resistor in FIG. 9
c is the effective damping of the equivalent spring-mass system
V_{DC} is the DC bias voltage applied to the resonator
\tilde{V}_{ac} is the ac voltage applied to the actuation electrode in Laplace domain
g is fabricated gap between the resonator and the actuation/sensing electrodes
C₁₆₀ is the nominal actuation/sensing capacitance when the displacement of the resonator is 0 μm.
s is the complex frequency variable in Laplace domain

$$Equation for {I}_{in} at resonance in terms of measured and estimated \\ quantities$$

$${\tilde{I}}_{i n} = {sC}_{i n} {\tilde{V}}_{a c} + s {C}_{160} \frac{{V}_{D C}}{g} \frac{1}{2} [ \frac{{C}_{160} \frac{{V}_{D C}}{g} {\tilde{V}}_{a c}}{s c} ] - {sC}_{f} [ \frac{{C}_{f}}{{C}_{totalR}} {\tilde{V}}_{a c} + \frac{{\tilde{V}}_{a c}}{2} [ \frac{{C}_{160}}{{C}_{totalR}} \frac{{V}_{D C}}{g} ] [ ( \frac{{C}_{160} \frac{{V}_{D C}}{g}}{s c} ) ] ] \qquad Equation 18$$

where:
Ĩᵢₙ is the Laplace form of the input current iᵢₙ, in FIG. 9
Cᵢₙ is the input capacitance of the resonator looking from terminal at which v_{ac} is connected
s is complex frequency variable in the Laplace domain
\tilde{V}^{ac} is the Laplace form of the input ac voltage v_{ac}
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
c is the effective damping of the equivalent spring-mass system
C_{f} is the feedthrough capacitance of the system
C_{totalR} is the sum of all capacitances which have output node/electrode of the resonator as one of their terminals, when the sensing electrode of the resonator terminated in a resistor as in FIG. 9

$$Equation for power input at resonance in case when resonator is resistively terminated$$

$${P}_{inresR} = {V}_{a c} ∠ {0}^{0} * {[ \frac{{V}_{a c} ∠ {0}^{0}}{2 c} ] [ {C}_{160} \frac{{V}_{D C}}{g} ]}^{2} = s {C}_{160} {β}_{Rres} {V}_{a c}^{2} \qquad Equation 19$$

where:
P_{inresR} is the active power input to the resonator, at resonant frequency, when the resonator is terminated in a resistive load as in FIG. 9
V_{ac}∠0° is the phasor form of the input ac voltage
c is the effective damping of the equivalent spring-mass system
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
s is complex frequency variable in the Laplace domain
β_{Rres} is gain coefficient of the dependent voltage-controlled voltage-source at the resonance frequency when the resonator is terminated in load resistor R and the applied DC voltage is V_{DC}

$$Equation for power output to the termination resistor at resonance , FIG . 9$$

$${P}_{outresR} \approx {[ {\frac{{V}_{a c} ∠ {0}^{0}}{2 s c} [ {C}_{160} \frac{{V}_{D C}}{g} ]}^{2} [ \frac{1}{{C}_{totalR}} ] ]}^{2} \frac{1}{R} = {β}_{R r e s} * {β}_{R r e s} \frac{{C}_{160}^{2}}{{C}_{totalR}} {V}_{a c} * \frac{{V}_{a c}}{R {C}_{totalR}} \qquad Equation 20$$

where:
P_{outresR} is the active power output from the resonator, at resonant frequency, and delivered to the load resistor R when the resonator is terminated in a resistive load as in FIG. 9
V_{ac}∠0° is the phasor form of the input ac voltage
c is the effective damping of the equivalent spring-mass system
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
s is complex frequency variable in the Laplace domain
β_{Rres} is gain coefficient of the dependent voltage-controlled voltage-source at the resonance frequency when the resonator is terminated in load resistor R and the applied DC voltage is
C_{totalR} is the total capacitance linking to the sensing electrode of the resonator when the resonator is terminated in the load resistor R
R is the load resistor in FIG. 9
\tilde{V}_{ac} is the Laplace form of the applied input ac voltage v_{ac}

$$Power gain equation$$

$$\frac{{P}_{outres}}{{P}_{inres}} = \frac{{V}_{6 res}}{{V}_{a c}} \frac{1}{sR {C}_{totalR}} \qquad Equation 21$$

where:
P_{outresR} is the active power output from the resonator, at resonant frequency, and delivered to the load resistor R when the resonator is terminated in a resistive load as in FIG. 9
P_{inresR} is the active power input to the resonator, at resonant frequency, when the resonator is terminated in a resistive load as in FIG. 9
\tilde{V}₆ᵣₑₛ is the Laplace form of the voltage at sensing electrode, in this case, at resonant frequency, as in FIG. 9
\tilde{V}_{ac} is the Laplace form of the applied input ac voltage v_{ac}
s is complex frequency variable in the Laplace domain
R is the load resistor in FIG. 9
C_{totalR} is the total capacitance linking to the sensing electrode of the resonator when the resonator is terminated in the load resistor R

In accordance with equation 21, power gain greater than 1 is achieved when R is in a suitable range. In our specific case, given that V₆ᵣₑₛ/V_{ac}=20, if the value of R is such that 1 «ω₀RC_{totalR}<20, the power gain of the MEM structure is >1.

$$Equation for voltage at sensing electrode in case of resistive termination$$

$${\tilde{V}}_{6} = \frac{{sRC}_{160} \frac{{V}_{D C}}{g} {\tilde{X}}_{2} + {sRC}_{f} {\tilde{V}}_{a c}}{[ 1 + {sRC}_{totalR} ]} \qquad Equation 22$$

where:
V₆ is the Laplace form of the voltage at sensing electrode, electrode 6 in the shown cases, as in FIG. 9
s is complex frequency variable in the Laplace domain
R is the load resistor in FIG. 9
C₁₆₀ is the nominal actuation/sensing capacitance when the displacement of the resonator is 0 μm.
V_{DC} is the DC bias voltage applied to the resonator
g is fabricated gap between the resonator and the actuation/sensing electrodes
\tilde{X}₂ is the Laplace form of the displacement of the sensed arm of the exemplary DETF
C_{f} is the feedthrough capacitance of the system
\tilde{V}_{ac} is the Laplace form of the applied input ac voltage v_{ac}
C_{totalR} is the total capacitance linking to the sensing electrode of the resonator when the resonator is terminated in the load resistor R

In accordance with equation 22, Case 1: sRC_{totalR} «1

In particular, the condition for signal gain to be greater 1 for this case is

$${V}_{D C} > \vert \frac{g}{{\tilde{X}}_{2}} \vert \frac{1}{{sRC}_{160}} .$$

Case 2: sRC_{totalR} »1 or R»1/sC_{totalR}. Thus, signal-gain (G_{S})

$$Equation for signal - gain in case of resistive termination$$

$${G}_{s} = \frac{1}{2} [ \frac{{C}_{160}}{{C}_{totalR}} \frac{{V}_{D C}}{g} ] [ ( \frac{{C}_{160} \frac{{V}_{D C}}{g}}{s c} ) ] \qquad Equation 23$$

where:
G_{S} is the voltage signal gain from input ac voltage to the resonator to the output ac voltage from the resonator at resonant frequency
C₁₆₀ is the nominal actuation/sensing capacitance when the displacement of the resonator is 0 μm.
C_{totalR} is the total capacitance linking to the sensing electrode of the resonator when the resonator is terminated in the load resistor R
V_{DC} is the DC bias voltage applied to the resonator
g is fabricated gap between the resonator and the actuation/sensing electrodes
s is complex frequency variable in the Laplace domain
c is the effective damping of the equivalent spring-mass system

In accordance with equation 23, defining

$${β}_{r e s} = \frac{1}{2} [ \frac{{V}_{D C}}{g} ] [ ( \frac{{C}_{160} \frac{{V}_{D C}}{g}}{s c} ) ] .$$

$$Equation for signal - gain in case of resistive termination in terms of {β}_{res}$$

$${G}_{S} = {β}_{r e s} \frac{{C}_{160}}{{C}_{totalR}} \qquad Equation 24$$

where:
β_{Rres} is gain coefficient of the dependent voltage-controlled voltage-source at the resonance frequency when the resonator is terminated in load resistor R and the applied DC voltage is V_{DC}
V_{DC} is the DC bias voltage applied to the resonator
g is fabricated gap between the resonator and the actuation/sensing electrodes
C₁₆₀ is the nominal actuation/sensing capacitance when the displacement of the resonator is 0 μm.
s is complex frequency variable in the Laplace domain
c is the effective damping of the equivalent spring-mass system
G_{S} is the voltage signal gain from input ac voltage to the resonator to the output ac voltage from the resonator at resonant frequency
C_{totalR} is the total capacitance linking to the sensing electrode of the resonator when the resonator is terminated in the load resistor R

In accordance with equation 24, G_{R}>1 condition is met when

$$Defining voltage - gain condition$$

$$Voltage gain = {G}_{S} = {β}_{r e s} \frac{{C}_{160}}{{C}_{totatR}} > 1 \qquad Equation 25$$

where:
C₁₆₀ is the nominal actuation/sensing capacitance when the displacement of the resonator is 0 μm.
G_{S} is the voltage signal gain from input AC voltage to the resonator to the output ac voltage from the resonator at resonant frequency
C_{totalR} is the total capacitance linking to the sensing electrode of the resonator when the resonator is terminated in the load resistor R

FIG. 12 illustrates a schematic diagram 1200 of DETF resonator with multiple actuation and sensing points along with the sensing element, in accordance with some embodiments of the present disclosure. In accordance with FIG. 12, quiescent tuning voltages bV_{DC}, and cV_{DC} may be same or different depending upon the potential provided to the seal- and substrate-layer. Further, FIG. 12 illustrates various feedthrough capacitances which are involved in the operation of the exemplary system of the present subject matter. A person skilled in the art will appreciate that presented concepts, figures, and equations may be generalized for any generic case of capacitively transduced MEM resonator systems with arbitrary number of inputs, n, and arbitrary number of outputs. In FIG. 12, the electrical connections in a voltage measurement configuration are illustrated. In the voltage measurement configuration, as shown in FIG. 12, output electrodes 6 and 3 of the resonator is kept electrically floating. Further, the actuation is carried out using electrodes 6′ and 3′. It would be appreciated by a person skilled in the art that, FIG. 12 may be implemented by any system which keeps the values of vₒ₁ and vₒ₂ at any electrically floating potential.

In some embodiments, since gap closing capacitive resonators are non-linear systems, to have considerable voltage response at the input frequency compared to the response at harmonic frequencies, a DC voltage source, V_{DC}, is applied to the electrode 1 of the resonator as illustrated in FIG. 12. In addition, linearity of such gap-closing resonators may be improved by maintaining the resonant beams unbent when the applied ac signal, v_{ac1} or v_{ac2}, is 0V. Further, electrode 2′,4′, 5′, and 7′ are connected to the ground potential to have balanced DC electrostatic forces on the actuation arm of the resonator.

Since potential on electrode 6 is determined by the electric potentials on the capacitances surrounding this electrode, a control knob bV_{DC} is created on the electrodes 5 & 7, and a control knob cV_{DC} is created on the electrodes 2 & 4 to adjust the DC potential on electrodes 6 and 3 to 0V as the resonator potential is varied for a given set of coaxial cables and connectors connecting the sensing electrode and the input terminal of the amplifier. Amongst remaining electrodes, 3 and 8 are connected to the ground potential.

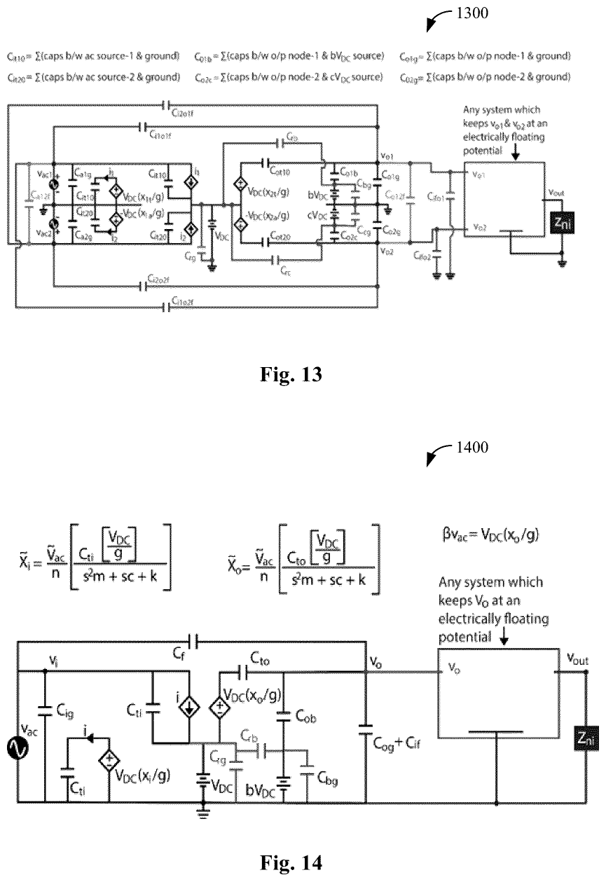

FIG. 13 illustrates an equivalent circuit diagram 1300 of the combined system of the resonator and the sensing element with multiple inputs and outputs, in accordance with some embodiments of the present disclosure. In accordance with FIG. 13, actuation- and sensing-capacitances are viewed as dependent sources. As illustrated in FIG. 13, in some embodiments, on the actuation beam dependent current source models the effect of transduced, time-varying input-capacitance, and on the sensing side dependent voltage source models the effect of the change in transduced, time-varying output-capacitance. Various capacitances are defined in the figure itself.

FIG. 14 illustrates an equivalent circuit diagram 1400 of the combined system of the resonator and the sensing element with single input and single output, in accordance with some embodiments of the present disclosure. In accordance with FIG. 14, transduced actuation- and sensing-capacitances are viewed as dependent sources. As illustrated in FIG. 14, in some embodiments, on the actuation beam dependent current source models the effect of transduced, time-varying input-capacitance and on the sensing side dependent voltage source models the effect of the change in transduced, time-varying output-capacitance.

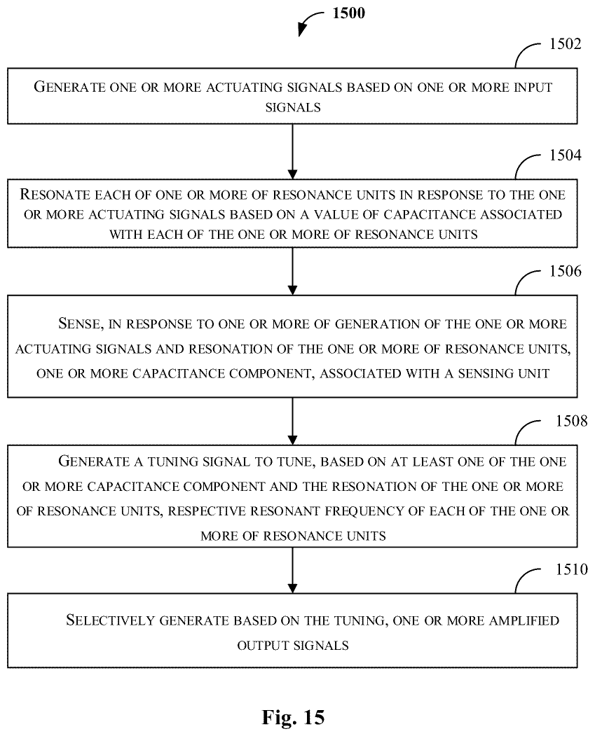

FIG. 15 illustrates a flowchart of a method 1500 for implementing Micro Electro-mechanical (MEM) resonator systems or Nano Electro-mechanical (NEM) resonator systems as a signal amplifier, in accordance with some embodiments of the present disclosure an aspect of the subject matter in accordance with one embodiment.

As illustrated in FIG. 15, the method 1500 may comprise one or more steps. The method 1500 may be described in the general context of computer executable instructions.

The order in which the method 1500 is described is not intended to be construed as a limitation, and any number of the described method blocks can be combined in any order to implement the method. Additionally, individual blocks may be deleted from the methods without departing from the scope of the subject matter described herein. Furthermore, the method can be implemented in any suitable hardware, software, firmware, or combination thereof.

At step 1502, one or more actuating units may generate one or more actuating signals based on one or more input signals.

At step 1504, each of one or more of resonance units, coupled to the one or more actuating units, may resonate, in response to the one or more actuating signals based on a value of capacitance associated with each of the one or more of resonance units.

At step 1506, one or more capacitance component, associated with the sensing unit, may be sense by the sensing unit, capacitively coupled to the one or more resonance units, and in response to one or more of generation of the one or more actuating signals and resonation of the one or more of resonance units.

At step 1508, an adaptive tuning unit, coupled to the sensing unit, may generate a tuning signal to tune, based on at least one of the one or more capacitance component and the resonation of the one or more of resonance units, respective resonant frequency of each of the one or more of resonance units.

At step 1510, the adaptive tuning unit, coupled to the sensing unit, may selectively generate one or more amplified output signals based on the tuning.

In an embodiment, the method 1500 may further comprise sensing, by the sensing unit and in response to one or more of generation of the one or more actuating signals and resonation of the one or more of resonance units, an output signal. Inan example, the output signal comprises summation of one or more of resonated signals from the one or more of resonance units.

In an embodiment, the sensing unit may be coupled to a Direct Current (DC) bias voltage generation unit. In the embodiment, the method 1500 may further comprise generating, by the DC bias voltage generation unit, a DC bias voltage, wherein the DC bias voltage is transferred to the adaptive tuning unit. The adaptive tuning unit may be configured to generate, based on the DC bias voltage, the tuning signal to tune the respective resonant frequency of each of the one or more of resonance units.

In an embodiment, the sensing unit may be coupled to an Alternating Current (AC) bias voltage generation unit. In an embodiment, the method 1500 may further comprise generating, by the AC bias voltage generation unit, an AC bias voltage. The AC bias voltage may be transferred to the adaptive tuning unit. The adaptive tuning unit may be configured to generate, based on the AC bias voltage, the tuning signal to tune the respective resonant frequency of each of the one or more of resonance units.

In an embodiment, the method 1500 may further comprise amplifying, by a sensing amplifier coupled to the sensing unit, an output signal received from the sensing unit. In an example, a Low Pass Filter (LPF), coupled to the sensing amplifier, may attenuate high-frequency noise components above a predetermined cutoff frequency, from the amplified output signal received from the sensing amplifier. In an embodiment, a signal processing element, coupled to the LPF, may be process a filtered signal received from the LPF. In an example, the signal processing element may transfer the processed signal to the adaptive tuning unit. The adaptive tuning unit may be configured to tune the respective resonant frequency of each of the one or more of resonance units.

### Voltage Tunable Frequency Selective Amplifier

As discussed in equivalent circuit model section, as per the present subject matter, resonator at output node may be viewed as a voltage dependent voltage source (when measured output signal is voltage) and its gain value is βv_{ac}. If the condition (βC₁₆₀/C_{totalVA})>1 is implemented, then the circuit model may show amplification and micro/nano electromechanical resonator made from the moveable mechanical structure may act as an electrical signal/power amplifier.

As per one or more embodiments, or a combination thereof, the present disclosure illustrates the following:
1) A capacitively transduced Micro/Nano electromechanical resonator implemented as a RF voltage amplifier with a single input and a single output with the output voltage being measured at an electrically floating electrode that is capacitively coupled with the resonator. The amplifier may be a narrow-band amplifier with the centre frequency specified by the resonant frequency of the Micro/Nano electromechanical resonators.
2) Multiple capacitively transduced Micro/Nano electromechanical resonators implemented as voltage amplifiers that share a common floating electrode such that the k^{th} resonator is actuated with voltage Vᵢₙₖ, with primary sinusoidal component at resonant frequency of the kth resonator, ωₖ. The resonant frequencies of the resonant amplifiers may or may not be equal. The output measured at the common floating electrode may be designed to be a linear combination of all the input voltages with the coefficients of voltage terms being set as per design and tuneable through separate tuning voltages.
3) Voltage amplification of difference of two voltage signals through application of these signals to two input capacitive drive electrodes of a single micro/nano electromechanical resonator such that they apply opposing forces on the resonator device and the amplified output voltage may be measured at the floating output electrode that is capacitively coupled with the resonator.
4) A micro/nano electromechanical resonator implemented as a phase shift amplifier with input voltage signal applied to one of the actuating electrodes and the resonant frequency tuned using bias voltage applied to the resonator body as well as voltage applied to other electrodes that affect the resonant frequency of the resonator such that the phase of the amplified voltage measured at the electrically floating output electrode may vary from −45° to −135°. The displacement response of a resonator as a function of frequency shows that for the relative phase of the displacement with respect to input voltage varies from −45° to −135° and, hence, the desired output phase may be obtained by appropriate choice of resonant frequency with respect to the input frequency. Furthermore, the output signal may also be obtained at an angle in the range 45° to 135°, by using an electrically-floating output-electrode that is placed on opposite side of the moving resonant structure that measures output at 180° phase compared to the above-mentioned electrically-floating electrode that may be yield signal at a phase angle of −45° to −135 degrees. Thus, a single resonator may act as a phase shifting amplifier that may address an overall angle range of 180°. A cascaded two resonator system may achieve phase shift of any angle from 0° to 360°.
5) A system of micro/nanomechanical resonators wherein input voltages Vᵢₙ₁, Vᵢₙ₂, . . . and Vᵢₙₖ are phase shifted to desired phase angles θ₁, θ₂, . . . and θₖ respectively and the phase shifted voltages are summed using the embodiment mentioned in claim number 2 wherein all the voltages are added with desired coefficients.
6) A capacitively transduced Micro/Nano electromechanical resonator implemented as a RF power amplifier with a single input and a single output with the output voltage being measured at an electrically floating electrode that is capacitively coupled with the resonator. The amplifier is a narrow-band amplifier with the centre frequency specified by the resonant frequency of the Micro/Nano electromechanical resonators.
7) Multiple capacitively transduced Micro/Nano electromechanical resonators implemented as power amplifiers that share a common floating electrode such that the k^{th} resonator is actuated with voltage Vᵢₙₖ, with primary sinusoidal component at resonant frequency of the kth resonator, ωₖ. The resonant frequencies of the resonant amplifiers may or may not be equal. The output measured at the common floating electrode may be designed to be a linear combination of all the input voltages with the coefficients of voltage terms being set as per design and tuneable through separate tuning voltages.
8) Power amplification of difference of two voltage signals through application of these signals to two input capacitive drive electrodes of a single micro/nano electromechanical resonator such that they apply opposing forces on the resonator device and the power amplified output voltage may be measured at the floating output electrode that is capacitively coupled with the resonator.

It will be understood by those within the art that, in general, terms used herein, and are generally intended as “open” terms (e.g., the term “including” should be interpreted as “including but not limited to,” the term “having” should be interpreted as “having at least,” the term “includes” should be interpreted as “includes but is not limited to,” etc.). For example, as an aid to understanding, the detailed description may contain usage of the introductory phrases “at least one” and “one or more” to introduce recitations. However, the use of such phrases should not be construed to imply that the introduction of a recitation by the indefinite articles “a” or “an” limits any particular part of description containing such introduced recitation to inventions containing only one such recitation, even when the introductory phrases “one or more” or “at least one” and indefinite articles such as “a” or “an” (e.g., “a” and/or “an” should typically be interpreted to mean “at least one” or “one or more”) are included in the recitations; the same holds true for the use of definite articles used to introduce such recitations. In addition, even if a specific part of the introduced description recitation is explicitly recited, those skilled in the art will recognize that such recitation should typically be interpreted to mean at least the recited number (e.g., the bare recitation of “two recitations,” without other modifiers, typically means at least two recitations, or two or more recitations).

The following provides an overview of aspects/examples of the present disclosure:

In some aspects, the present disclosure discloses a capacitively transduced Micro or Nano Electro Mechanical Resonator system is provided. The capacitively transduced Micro or Nano Electro Mechanical Resonator system comprises one or more actuating units, one or more resonance units, a sensing unit, and an adaptive tuning unit. The one or more actuating units is configured to generate one or more actuating signals based on one or more input signals. The one or more resonance units coupled to the one or more actuating units. Each of the one or more of resonance units is configured to resonate in response to the one or more actuating signals based on a value of capacitance associated with each of the one or more of resonance units. The sensing unit is capacitively coupled to the one or more resonance units. The sensing unit is configured to, in response to one or more of generation of the one or more actuating signals and resonation of the one or more of resonance units, sense one or more capacitance component, associated with the sensing unit. The adaptive tuning unit is coupled to the sensing unit, the adaptive tuning unit configured to generate a tuning signal to tune, based on at least one of the one or more capacitance component and the resonation of the one or more of resonance units, respective resonant frequency of each of the one or more of resonance units. Further, the adaptive tuning unit configured to selectively generate, based on the tuning, one or more amplified output signals.

In some aspects, the sensing unit comprises one or more sensing electrodes. The sensing amplifier is a differential amplifier. The amplified output signal is associated with one of an amplified voltage signal and a phase shifted amplified signal. The capacitance component is one of a parasitic capacitance, an intended capacitance, or a stray capacitance.

In some of the related aspects, in response to one or more of generation of the one or more actuating signals and resonation of the one or more of resonance units, the sensing unit is configured to sense an output signal. The output signal comprises summation of one or more of resonated signals from the one or more of resonance units.

In some of the related aspects, the sensing unit is coupled to a Direct Current (DC) bias voltage generation unit configured to generate a DC bias voltage, wherein the DC bias voltage is transferred to the adaptive tuning unit. The adaptive tuning unit is configured to generate, based on the DC bias voltage, the tuning signal to tune the respective resonant frequency of each of the one or more of resonance units.

In some of the related aspects, the sensing unit is coupled to an Alternating Current (AC) bias voltage generation unit configured to generate an AC bias voltage, wherein the AC bias voltage is transferred to the adaptive tuning unit. The adaptive tuning unit is configured to generate, based on the AC bias voltage, the tuning signal to tune the respective resonant frequency of each of the one or more of resonance units.

In some of the related aspects, the resonator system further comprises a sensing amplifier coupled to the sensing unit, and configured to amplify an output signal received from the sensing unit. The resonator system further comprises a Low Pass Filter (LPF) coupled to the sensing amplifier, and configured to attenuate high-frequency noise components above a predetermined cutoff frequency, from the amplified output signal received from the sensing amplifier. The resonator system further comprises a signal processing element coupled to the LPF, and configured to process a filtered signal received from the LPF, and transfer the processed signal to the adaptive tuning unit. The adaptive tuning unit is configured to tune the respective resonant frequency of each of the one or more of resonance units.

In some of the related aspects, the signal processing element is configured to receive one or more input signals comprising the filtered signal, received from the LPF, and a reference voltage, process the one or more input signals, and transfer the processed input signal to the adaptive tuning unit. The adaptive tuning unit is configured to generate, based on the processed input signal, the tuning signal to tune the respective resonant frequency of each of the one or more of resonance units.

In some of the related aspects, to tune the respective resonant frequency of each of the one or more of resonance units, the adaptive tuning unit is configured to apply a Direct Current (DC) bias voltage to one or more electromechanical elements of each of the one or more of resonance units to shift the phase of the one or more input signals, and generate an output value by adding the one or more of phase shifted input signals.

In some of the related aspects, one or more structural parameters of the resonator system are configured to be dynamically modified. The adaptive tuning unit is further configured to generate an output value by adding the one or more amplified output signals pertaining to the dynamically modified one or more structural parameters.

In some of the related aspects, the one or more actuating units are configured to receive one or more of input signals, and wherein the adaptive tuning unit is configured to shift a phase of each of the one or more of input signals to a predetermined phase angle, and generate an output value by adding the one or more of phase shifted input signals.

In some of the related aspects, to tune the respective resonant frequency of each of the one or more of resonance units, the adaptive tuning unit is configured to apply individual Direct Current (DC) bias voltage to one or more electromechanical elements of each of the one or more of resonance units to shift the phase of each of the one or more of phase shifted input signals.

In some of the related aspects, the resonator system of claim 1, further comprises a phase shifting element comprising a low pass filter, configured to shift the phase of the detected and amplified signal by a value in a range of 45 to 135 degrees or −45 to −135 degrees.

In some of the related aspects, the one or more input signals is an input voltage signal, and where, to tune the respective resonant frequency of each of the one or more of resonance units, the adaptive tuning unit is configured to apply a Direct Current (DC) bias voltage to one or more electromechanical elements of each of the one or more of resonance units to amplify a voltage component of the input voltage signal.

In some of the related aspects, the one or more input signals is an input voltage signal, and wherein the one or more actuating units are configured to receive one or more of input voltage signals, and wherein the adaptive tuning unit is configured to amplify a voltage component of each of the one or more of input voltage signals to a predetermined voltage, and generate an output value by adding the one or more of amplified input voltage signals.

In some of the related aspects, the one or more input signals is an input voltage signal, and where, to tune the respective resonant frequency of each of the one or more of resonance units, the adaptive tuning unit is configured to apply individual Direct Current (DC) bias voltage to one or more electromechanical elements of each of the one or more of resonance units to amplify the voltage component of each of the one or more of input voltage signals.

In some of the related aspects, the resonator system further comprises an enclosure enclosing at least one of the actuating unit, the resonance unit, the sensing unit, and the adaptive tuning unit.

In some aspects, the present disclosure discloses a method for implementing Micro Electro-Mechanical (MEM) devices or Nano Electro-Mechanical (NEM) devices as a signal amplifier is provided. The method comprises generating, by one or more actuating units, one or more actuating signals based on one or more input signals. Further, the method comprises resonating each of one or more of resonance units coupled to the one or more actuating units, in response to the one or more actuating signals based on a value of capacitance associated with each of the respective one or more of resonance units. The method further comprises sensing, by the sensing unit capacitively coupled to the one or more resonance units and in response to one or more of generation of the one or more actuating signals and resonation of the one or more of resonance units, one or more capacitance component, associated with the sensing unit. Furthermore, the method comprises generating, by an adaptive tuning unit coupled to the sensing unit, a tuning signal to tune, based on at least one of the one or more capacitance component and the resonation of the one or more of resonance units, respective resonant frequency of each of the one or more of resonance units. The method further comprises selectively generating, by the adaptive tuning unit coupled to the sensing unit, based on the tuning, one or more amplified output signals.

In some of the related aspects, the method further comprises sensing, by the sensing unit and in response to one or more of generation of the one or more actuating signals and resonation of the one or more of resonance units, an output signal, wherein the output signal comprises summation of one or more of resonated signals from the one or more of resonance units.

In some of the related aspects, the sensing unit is coupled to a Direct Current (DC) bias voltage generation unit, the method further comprises generating, by the DC bias voltage generation unit, a DC bias voltage, wherein the DC bias voltage is transferred to the adaptive tuning unit. The adaptive tuning unit is configured to generate, based on the DC bias voltage, the tuning signal to tune the respective resonant frequency of each of the one or more of resonance units.

In some of the related aspects, the sensing unit is coupled to an Alternating Current (AC) bias voltage generation unit, the method further comprises generating, by the AC bias voltage generation unit, an AC bias voltage, wherein the AC bias voltage is transferred to the adaptive tuning unit. The adaptive tuning unit is configured to generate, based on the AC bias voltage, the tuning signal to tune the respective resonant frequency of each of the one or more of resonance units.

In some of the related aspects, the method further comprises amplifying, by a sensing amplifier coupled to the sensing unit, an output signal received from the sensing unit, attenuating, by a Low Pass Filter (LPF) coupled to the sensing amplifier, high-frequency noise components above a predetermined cutoff frequency, from the amplified output signal received from the sensing amplifier, processing, by a signal processing element coupled to the LPF, a filtered signal received from the LPF, and transferring, by the signal processing element, the processed signal to the adaptive tuning unit. The adaptive tuning unit is configured to tune the respective resonant frequency of each of the one or more of resonance units.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following detailed description.

We claim:

1. A capacitively transduced Micro or Nano Electro Mechanical Resonator system, comprising:
one or more actuating units configured to generate one or more actuating signals based on one or more input signals;
one or more resonance units coupled to the one or more actuating units, wherein each of the one or more of resonance units is configured to resonate in response to the one or more actuating signals based on a value of capacitance associated with each of the respective one or more of resonance units;
a sensing unit capacitively coupled to the one or more resonance units, the sensing unit configured to, in response to one or more of generation of the one or more actuating signals and resonation of the one or more of resonance units, sense one or more capacitance component, associated with the sensing unit; and
an adaptive tuning unit coupled to the sensing unit, the adaptive tuning unit configured to:
generate a tuning signal to tune, based on at least one of the one or more capacitance component and the resonation of the one or more of resonance units, respective resonant frequency of each of the one or more of resonance units; and
selectively generate, based on the tuning, one or more amplified output signals.

2. The resonator system of claim 1, wherein,
the sensing unit comprises one or more sensing electrodes,
the amplified output signal is associated with one of an amplified voltage signal and a phase shifted amplified signal, and
the capacitance component is one of a parasitic capacitance, an intended capacitance, or a stray capacitance.

3. The resonator system of claim 1, wherein, in response to one or more of generation of the one or more actuating signals and resonation of the one or more of resonance units, the sensing unit is configured to sense an output signal, wherein the output signal comprises summation of one or more of resonated signals from the one or more of resonance units.

4. The resonator system of claim 1, wherein the sensing unit is coupled to a Direct Current (DC) bias voltage generation unit configured to:
generate a DC bias voltage, wherein the DC bias voltage is transferred to the adaptive tuning unit,
wherein the adaptive tuning unit is configured to generate, based on the DC bias voltage, the tuning signal to tune the respective resonant frequency of each of the one or more of resonance units.

5. The resonator system of claim 1, wherein the sensing unit is coupled to an Alternating Current (AC) bias voltage generation unit configured to:
generate an AC bias voltage, wherein the AC bias voltage is transferred to the adaptive tuning unit,
wherein the adaptive tuning unit is configured to generate, based on the AC bias voltage, the tuning signal to tune the respective resonant frequency of each of the one or more of resonance units.

6. The resonator system of claim 1, further comprises:
a sensing amplifier coupled to the sensing unit, and configured to amplify an output signal received from the sensing unit, wherein the sensing amplifier is a differential amplifier;
a Low Pass Filter (LPF) coupled to the sensing amplifier, and configured to attenuate high-frequency noise components above a predetermined cutoff frequency, from the amplified output signal received from the sensing amplifier; and
a signal processing element coupled to the LPF, and configured to:
process a filtered signal received from the LPF; and
transfer the processed signal to the adaptive tuning unit,
wherein the adaptive tuning unit is configured to tune the respective resonant frequency of each of the one or more of resonance units.

7. The resonator system of claim 6, wherein the signal processing element is configured to:
receive one or more input signals comprising the filtered signal, received from the LPF, and a reference voltage;
process the one or more input signals; and
transfer the processed input signal to the adaptive tuning unit,
wherein the adaptive tuning unit is configured to generate, based on the processed input signal, the tuning signal to tune the respective resonant frequency of each of the one or more of resonance units.

8. The resonator system of claim 1, wherein, to tune the respective resonant frequency of each of the one or more of resonance units, the adaptive tuning unit is configured to:
apply a Direct Current (DC) bias voltage to one or more electromechanical elements of each of the one or more of resonance units to shift the phase of the one or more input signals; and
generate an output value by adding the one or more of phase shifted input signals.

9. The resonator system of claim 1, wherein one or more structural parameters of the resonator system are configured to be dynamically modified, and
the adaptive tuning unit is further configured to:
generate an output value by adding the one or more amplified output signals pertaining to the dynamically modified one or more structural parameters.

10. The resonator system of claim 1, wherein the one or more actuating units are configured to receive one or more of input signals, and wherein the adaptive tuning unit is configured to:
shift a phase of each of the one or more of input signals to a predetermined phase angle; and
generate an output value by adding the one or more of phase shifted input signals.

11. The resonator system of claim 10, wherein, to tune the respective resonant frequency of each of the one or more of resonance units, the adaptive tuning unit is configured to apply individual Direct Current (DC) bias voltage to one or more electromechanical elements of each of the one or more of resonance units to shift the phase of each of the one or more of phase shifted input signals.

12. The resonator system of claim 1, further comprises a phase shifting element comprising a low pass filter, configured to shift the phase of the detected and amplified signal by a value in a range of 45 to 135 degrees or −45 to −135 degrees.

13. The resonator system of claim 1, wherein the one or more input signals is an input voltage signal, and wherein, to tune the respective resonant frequency of each of the one or more of resonance units, the adaptive tuning unit is configured to apply a Direct Current (DC) bias voltage to one or more electromechanical elements of each of the one or more of resonance units to amplify a voltage component of the input voltage signal.

14. The resonator system of claim 1, wherein the one or more input signals is an input voltage signal, and wherein the one or more actuating units are configured to receive one or more of input voltage signals, and wherein the adaptive tuning unit is configured to:
amplify a voltage component of each of the one or more of input voltage signals to a predetermined voltage; and
generate an output value by adding the one or more of amplified input voltage signals.

15. The resonator system of claim 1, wherein the one or more input signals is an input voltage signal, and wherein, to tune the respective resonant frequency of each of the one or more of resonance units, the adaptive tuning unit is configured to apply individual Direct Current (DC) bias voltage to one or more electromechanical elements of each of the one or more of resonance units to amplify a voltage component of each of the one or more of input voltage signals.

16. The resonator system of claim 1, further comprises:
an enclosure enclosing at least one of the actuating unit, the resonance unit, the sensing unit, and the adaptive tuning unit.

17. A method comprising:
generating, by one or more actuating units, one or more actuating signals based on one or more input signals;
resonating each of one or more of resonance units coupled to the one or more actuating units, in response to the one or more actuating signals based on a value of capacitance associated with each of the one or more of resonance units;
sensing, by the sensing unit capacitively coupled to the one or more resonance units and in response to one or more of generation of the one or more actuating signals and resonation of the one or more of resonance units, one or more capacitance component, associated with the sensing unit;
generating, by an adaptive tuning unit coupled to the sensing unit, a tuning signal to tune, based on at least one of the one or more capacitance component and the resonation of the one or more of resonance units, respective resonant frequency of each of the one or more of resonance units; and
selectively generating, by the adaptive tuning unit coupled to the sensing unit, based on the tuning, one or more amplified output signals.

18. The method of claim 17, further comprising:
sensing, by the sensing unit and in response to one or more of generation of the one or more actuating signals and resonation of the one or more of resonance units, an output signal, wherein the output signal comprises summation of one or more of resonated signals from the one or more of resonance units.

19. The method of claim 17, wherein the sensing unit is coupled to a Direct Current (DC) bias voltage generation unit, the method further comprises:
generating, by the DC bias voltage generation unit, a DC bias voltage, wherein the DC bias voltage is transferred to the adaptive tuning unit,
wherein the adaptive tuning unit is configured to generate, based on the DC bias voltage, the tuning signal to tune the respective resonant frequency of each of the one or more of resonance units.

20. The method of claim 17, wherein the sensing unit is coupled to an Alternating Current (AC) bias voltage generation unit, the method further comprises:
generating, by the AC bias voltage generation unit, an AC bias voltage, wherein the AC bias voltage is transferred to the adaptive tuning unit,
wherein the adaptive tuning unit is configured to generate, based on the AC bias voltage, the tuning signal to tune the respective resonant frequency of each of the one or more of resonance units.

21. The method of claim 17, further comprising:
amplifying, by a sensing amplifier coupled to the sensing unit, an output signal received from the sensing unit;
attenuating, by a Low Pass Filter (LPF) coupled to the sensing amplifier, high-frequency noise components above a predetermined cutoff frequency, from the amplified output signal received from the sensing amplifier; and
processing, by a signal processing element coupled to the LPF, a filtered signal received from the LPF; and
transferring, by the signal processing element, the processed signal to the adaptive tuning unit,
wherein the adaptive tuning unit is configured to tune the respective resonant frequency of each of the one or more of resonance units.
